(19) United States
(12) Patent Application Publication
(10) Pub. No.: US 2005/0139257 A1
(43) Pub. Date: Jun. 30, 2005

(54) Photosensitizing transition metal complex containing quaterpyridine and photovoltaic cell with the metal complex

(75) Inventors: Ashraful Islam, Yamatotakada-shi (JP); Liyuan Han, Kitakatsuragi-gun (JP); Atsushi Fukui, Kashiba-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, OSAKA (JP)

(21) Appl. No.: 11/017,649

(22) Filed: Dec. 22, 2004

(30) Foreign Application Priority Data
Dec. 26, 2003 (JP) 2003-432155

(51) Int. Cl. H01L 31/00

(52) U.S. Cl. 136/263

(57) ABSTRACT

A photosensitizer complex of formula (I) MLX₂ in which M is a transition metal selected from ruthenium, osmium, iron, rhenium and technetium; each X is a co-ligand independently selected from NCS⁻, Cl⁻, Br⁻, I⁻, CN⁻, H₂O; pyridine unsubstituted or substituted by at least one group selected from vinyl, primary, secondary or tertiary amine, OH and C₁₋₃₀ alky, preferably NSC⁻ and CN⁻. L is a tetradentate polypyridine ligand, carrying at least one carboxylic, phosphoric acid or a chelating group and one substituted or unsubstituted alkyl group having 1 to 50 carbon atoms, substituted or unsubstituted alkylamide group having 2 to 30 carbon atoms or substituted or unsubstituted aralkyl group having 7 to 50 carbon atoms. A dye-sensitized electrode includes a substrate having an electrically conductive surface, an oxide semiconductor film formed thereon, and the above sensitizer of formula (I) as specified above, supported on the film.

This nonprovisional application is based on Japanese Patent Application No. 2003-432155 filed with the Japan Patent Office on Dec. 26, 2003, the entire contents of which are hereby incorporated by reference.

### BACKGROUND OF THE INVENTION

1. Field of the Invention

The invention relates to new photosensitizing transition metal complex and a photovoltaic cell such as solar cell with the metal complex.

2. Description of the Background Art

Photosensitive dyes are coated on metal oxide films rendering a device as solar cell effective in the conversion of visible light to electric energy. In this solar cell, a monolayer of dye is attached to the surface of nanocrystalline metal dioxide film. Photoexcitation of the dye results in the injection of an electron into the conduction band of the metal oxide. The original state of the dye is subsequently restored by electron donation from a redox system, such as the iodide/triiodide couple. Molecular design of ruthenium polypyridyl photosensitizers for nanocrystalline TiO₂ solar cells that can absorbs visible light of all colors presents a challenging task. The dye should have suitable ground- and excited state redox properties so that the two key electron transfer steps (charge injection and regeneration of the dye) occur efficiently.

The most efficient transition metal complexes employed so far in these solar cells are Ru(II) polypyridyl complexes because of their intense charge-transfer (CT) absorption in the whole visible range, moderately intense emission with fairly long lifetime in fluid solutions at ambient temperatures, high quantum yield for the formation of the lowest CT excited state, and redox reactivity and ease of tunability of redox properties. So far, the most successful sensitizer employed in these devices is cis-dithiocyanato-bis-(4,4′-dicarboxy-2,2′-bipyridine) ruthenium (II) complex. Recently, Graetzel et al. reported in Inorg. Chem. 41(2002) 367 panchromatic trans-ruthenium-polypyridine complexes containing quaterpyridine type ligand whose show intense charge-transfer (CT) absorption in the whole visible and near-IR region. Accordingly a new series of amphiphilic dyes with quaterpyridine type ligands having electron donating and/or protective group have been developed to act as a photosensitizer. The presence of hydrophobic chains improve the stability of the solar cell performance.

### SUMMARY OF THE INVENTION

The present invention aims to provide a new series of ptotochemicaly stable amphiphilic transition metal complexes to improve the efficiency, durability and stability of the dye sensitized nanocrystalline solar cell.

According to the invention, there is provided photosensitizing transition metal complexes represented by the formula (I)
MLX₂ (I)

In the formula, M is a transition metal selected from Ru(II), Os(II), Fe(II), Re(I) and Tc(I);

L is a polypyridine ligand having the general formula (II); 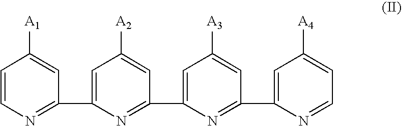
wherein A₁, A₂, A₃ and A₄ contain at least one anchoring group selected from —COOH, —COON(C₄H₉)₄, —PO(OH)₂, —PO(OR₁)₂ (where R₁ is an alkyl group having 1-30 carbon atoms), —CO(NHOH), and at least one group selected from an alkyl group having 1 to 50 carbon atoms, an alkylamide group having 2 to 50 carbon atoms or an aralkyl group having 7 to 50 carbon atoms, and in the case where there remains any one of A₁, A₂, A₃ and A₄, it may be a hyrogen atom; and X is a ligand selected from NCS⁻, Cl⁻, Br⁻, I⁻, CN⁻, NCO⁻, H₂O or pyridine group which may be substituted by vinyl, primary, secondary or tertiary amine, alkylthio, arylthio, hydroxyl or C₁₋₃₀ alkyl.

The present invention further provides a photovoltaic cell comprising a support, a conductive layer formed on the support, and a porous semiconductor layer formed on the conductive layer, wherein the porous semiconductor layer carries a photosensitizing transition metal complex as defined above.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagrammatic sectional view showing the structure of a solar cell constructed in the present invention.

### DESCRIPTION OF THE PREFERRED EMBODIMENTS

According to the invention, there is provided photosensitizing transition metal complexes represented by the formula (I):
MLX2 (I)

In the formula (I), the symbols or groups will be explained in detail.

The transition metal for M is preferred to be Ru(II) and Os(II).

The ligand for X is preferred to be NCS⁻ and CN⁻.

The polypyridine ligand for L is preferred to be formula (II); 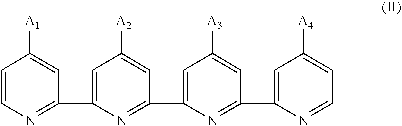
wherein A₁, A₂, A₃ and A₄ contain at least one anchoring group selected from —COOH, —COON(C₄H₉)₄ and —PO(OH)₂, and at least one group selected from an alkyl group having 6 to 30 carbon atoms, an alkylamide group having 2 to 30 carbon atoms or an aralkyl group having 7 to 30 carbon atoms, and in the case where there remains any one of A₁, A₂, A₃ and A₄, it may be a hydrogen atom; and the alkyl group and the alkyl moiety of the alkylamide group and aralkyl group may be either straight chain or branched.

The polypyridine ligand for the general formula (II) is preferred to be those of the subformula (IIa) and (IIb); 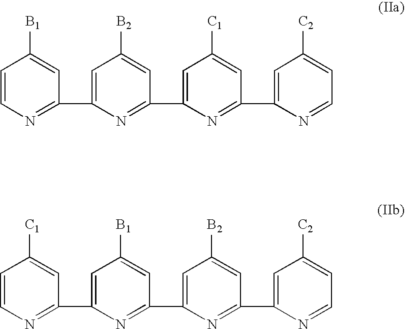
Where B₁ and B₂ are —COOH, —COON(C₄H₉)₄ or —PO(OH)₂; C₁ and C₂ are the same or different, a hydrogen atom, an alkyl group having 6-30 carbon atoms, provided that any one of C₁ and C₂ is different from a hydrogen atom.

Preferred polypyridine ligands for L, which can contribute for the best to increase the efficiency and stability of photovoltaic cell are those having at least one anchoring group of —COOH and —PO(OH)₂, specifically as mentioned below.

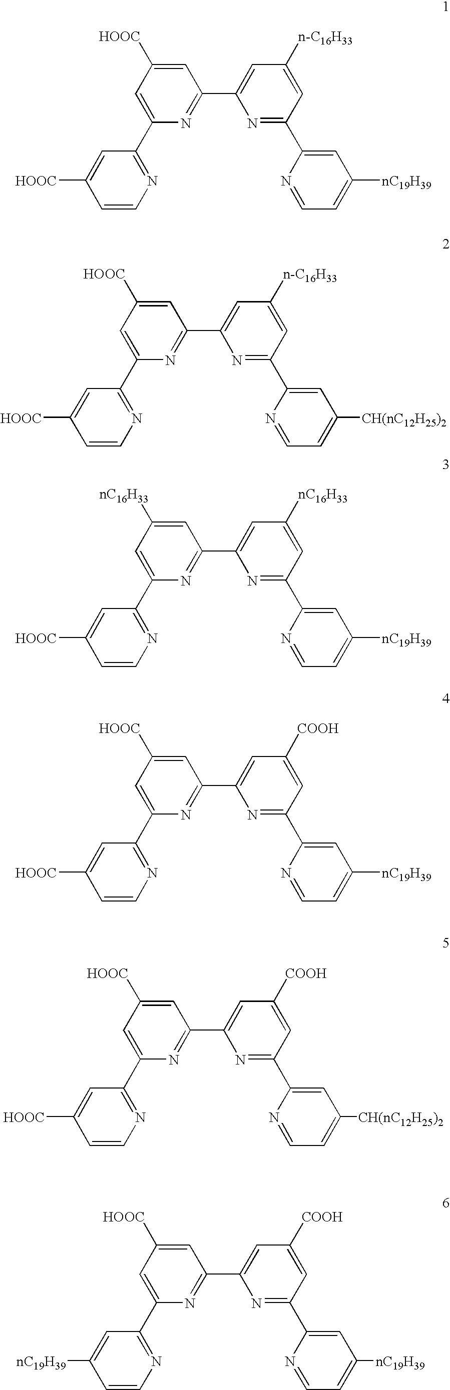

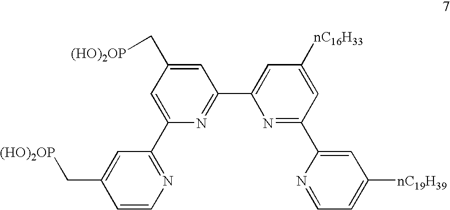

Specifically, preferred illustrative examples of the photosensitizing transition metal complexes of the general formula (I) are ruthenium complexes as shown by complex type A in Table 1.

TABLE 1

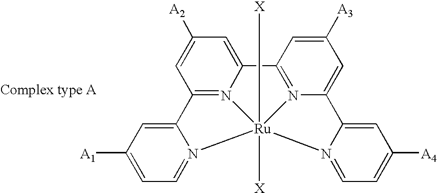

| Complex | | | | | |
|---|---|---|---|---|---|
| No | A₁ | A₂ | A₃ | A₄ | X |
| 1a | COOH | COOH | nC₁₆H₃₃ | nC₁₉H₃₉ | NSC— |
| 1b | COOH | COOH | nC₁₆H₃₃ | nC₁₉H₃₉ | CN— |
| 1c | COOH | COOH | nC₁₆H₃₃ | nC₁₉H₃₉ | I— |
| 1d | COOH | COOH | nC₁₀H₂₁ | nC₁₁H₂₃ | NSC— |
| 1e | COOH | COOH | nC₁₀H₂₁ | nC₁₁H₂₃ | CN— |
| 2a | COOH | COOH | nC₁₆H₃₃ | nCH(C₁₂H₂₅)₂ | NSC— |
| 2b | COOH | COOH | nC₁₆H₃₃ | nCH(C₁₂H₂₅)₂ | CN— |
| 2c | COOH | COOH | nC₁₆H₃₃ | nCH(C₁₂H₂₅)₂ | I— |
| 3a | COOH | nC₁₆H₃₃ | nC₁₆H₃₃ | nC₁₉H₃₉ | NSC— |
| 3b | COOH | nC₁₆H₃₃ | nC₁₆H₃₃ | nC₁₉H₃₉ | CN— |
| 3c | COOH | nC₁₆H₃₃ | nC₁₆H₃₃ | nC₁₉H₃₉ | I— |
| 4a | COOH | COOH | COOH | nC₁₉H₃₉ | NSC— |
| 4b | COOH | COOH | COOH | nC₁₉H₃₉ | CN |
| 4c | COOH | COOH | COOH | nC₁₉H₃₉ | I— |
| 4d | COOH | COOH | COOH | nC₁₁H₂₃ | NSC— |
| 4e | COOH | COOH | COOH | nC₁₁H₂₃ | CN |
| 5a | COOH | COOH | COOH | nCH(C₁₂H₂₅)₂ | NSC— |
| 5b | COOH | COOH | COOH | nCH(C₁₂H₂₅)₂ | CN— |
| 5c | COOH | COOH | COOH | nCH(C₁₂H₂₅)₂ | I— |
| 6a | nC₁₉H₃₉ | COOH | COOH | nC₁₉H₃₉ | NSC— |
| 6b | nC₁₉H₃₉ | COOH | COOH | nC₁₉H₃₉ | CN— |
| 6c | nC₁₉H₃₉ | COOH | COOH | nC₁₉H₃₉ | I— |
| 6d | nC₁₁H₂₃ | COOH | COOH | nC₁₁H₂₃ | NSC— |
| 7a | PO(OH)₂ | PO(OH)₂ | nC₁₆H₃₃ | nC₁₉H₃₉ | NSC— |
| 7b | PO(OH)₂ | PO(OH)₂ | nC₁₆H₃₃ | nC₁₉H₃₉ | CN— |
| 7c | PO(OH)₂ | PO(OH)₂ | nC₁₆H₃₃ | nC₁₉H₃₉ | I— |
| 8a | COOH | H | H | nC₁₀H₂₁ | NSC— |
| 8b | COOH | H | H | nC₁₀H₂₁ | CN— |
| 8c | COOH | H | H | nC₁₉H₃₉ | NSC— |
| 8d | COOH | H | H | nC₁₉H₃₉ | CN— |
| 8e | COOH | H | H | nCH(C₁₂H₂₅)₂ | NSC— |
| 8f | COOH | H | H | nCH(C₁₂H₂₅)₂ | CN— |
| 9a | COOH | COOH | H | nC₁₁H₂₃ | NSC— |
| 9b | COOH | COOH | H | nC₁₁H₂₃ | CN— |
| 9c | COOH | COOH | H | nC₁₉H₃₉ | NSC— |
| 9d | COOH | COOH | H | nC₁₉H₃₉ | CN— |
| 9e | COOH | COOH | H | nCH(C₁₂H₂₅)₂ | NSC— |
| 9f | COOH | COOH | H | nCH(C₁₂H₂₅)₂ | CN— |

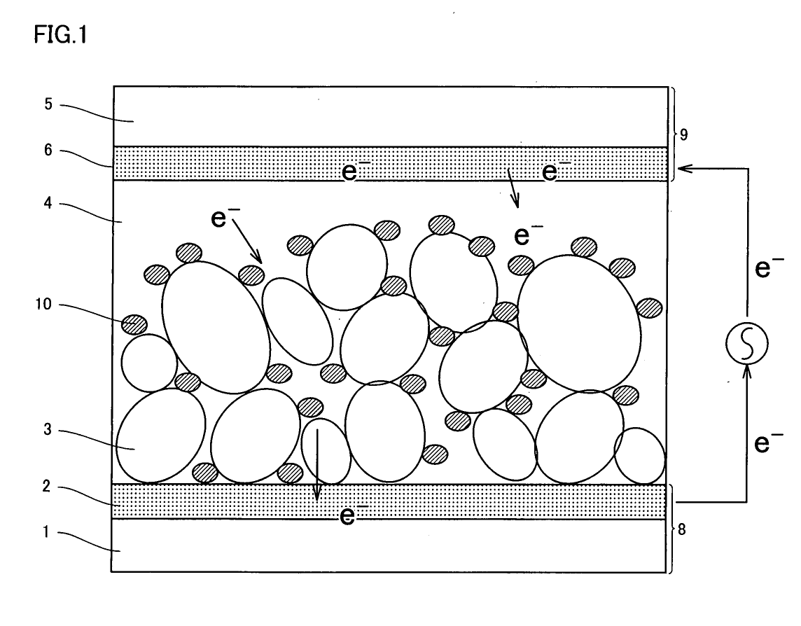

An embodiment of the invention will be described with reference to FIG. 1. A dye-sensitized solar cell shown in FIG. 1 has such a structure containing an electroconductive support 8 having formed thereon a porous photovoltaic layer 3 having a photosensitizing dye 10 adsorbed thereon and/or therein, a hole transporting layer 4 filled between the porous photovoltaic layer 3 and a support on a counter electrode side 9, and a sealant 7 sealing the side surfaces. The electroconductive support 8 is constituted with a substrate 1 and a transparent electroconductive film 2. The material used in the substrate 1 is not particularly limited and can be various kinds of transparent materials, and glass is preferably used. The material used in the transparent electroconductive film 2 is also not particularly limited, and it is preferred to use a transparent electroconductive metallic oxide electrode such as fluorine-doped tin oxide (SnO₂:F), antimony doped tin oxide (SnO₂:Sb), tin-doped indium oxide (In₂O₃:Sn), aluminium-doped zinc oxide (ZnO:Al) and gallium-dopped zinc oxide (ZnO:Ga). Examples of the method for forming the transparent electroconductive film 2 on the substrate 1 include a vacuum vapor deposition method, a sputtering method, a CVD (chemical vapor deposition) method and a PVD (physical vapor deposition) method using a component of the material, and a coating method by a sol-gel method.

The material of the porous semiconductor layer used in the porous photovoltaic layer 3 is not particularly limited as far as it is an n-type semiconductor. It is preferred to use an oxide semiconductor such as titanium oxide (TiO₂), zinc oxide (ZnO), tin oxide (SnO₂), indium oxide (In₂O₃) and niobium oxide (Nb₂O₃). It is preferred that the oxide semiconductor have a large surface area for reasons of obtaining high performance of a solar cell. Thus, the oxide semiconductor preferably has a particle diameter of 1 to 200 nm, more preferably 50 nm or less. The oxide semiconductor preferably has a specific surface area of 5 to 100 m2/g. The oxide semiconductor is immobilized on the conductive surface to form a generally porous film having a thickness of at least 200 nm, preferably 1000 to 30000 nm.

A dye sensitized semiconductor electrode according to the present invention may be obtained by fixing the above described metal complex of the present invention to a film or layer of oxide semiconductor particles formed on an electrically conductive surface of a substrate in any suitable conventional manner.

Fixation of the oxide semiconductor on the conductive surface may be effected by dipping, coating or any suitable known method, a layer of a suspension or slurry containing the oxide superconductor onto the conductive surface, followed by drying and calcinations. A water medium, which may contain a surfactant, a thickening agent such as polyethylene glycol and any suitable additive, is generally used for forming the suspension or slurry. The calcination is generally carried out at 300-900° C., preferably 400-600° C.

The metal complex is fixed to the semiconductor layer. The metal complex is dissolved in a suitable solvent such as methanol, ethanol, acetonitrile, n-butanol, tert-butanol or dimethylformamide. The above described semiconductor electrode is then impregnated with this solution by immersion, coating or any other suitable method. It is preferred that the solution penetrates deep into the porous layer of the oxide semiconductor. Thus, the semiconductor electrode is preferably evacuated at an elevated temperature to remove gases trapped therein. The metal complex preferably forms a monolayer on surfaces of the oxide semiconductor.

The support on a counter electrode side 9 is constituted by a substrate 5 and a counter electrode layer 6. The material used for the substrate 5 is not particularly limited as similar to the substrate 1, and it can be various kinds of transparent materials, with glass being preferably used. The material used for the counter electrode layer 6 is also not particularly limited, and one of a platinum thin film, a carbon thin film, fluorine-doped tin oxide (SnO₂:F), antimony doped tin oxide (SnO₂:Sb), tin-doped indium oxide (In₂O₃:Sn), aluminium-doped zinc oxide (ZnO:Al) and gallium-dopped zinc oxide (ZnO:Ga), an accumulated layer of plurality thereof, and a composite film of plurality thereof are preferably used. The role of the counter electrode layer 6 is to facilitate the transfer of electrons from the counterelectrode to the electrolyte. Examples of the method for forming the counter electrode film 6 on the substrate 5 include a vacuum vapor deposition method, a sputtering method, a CVD (chemical vapor deposition) method and a PVD (physical vapor deposition) method using a component of the material, and a coating method by a sol-gel method. A further possible modification of the counterelectrode is to make it reflective to light that has passed through the electrolyte and the first plate. Further the outside of the substrates may be coated with plastics like PS, PMMA, or preferably PC to protect the TiO₂ layer, the dyestuff and the electrolyte against UV-light to give long term stability.

In the invention, as the hole transporting layer 4 filled between the porous semiconductor layer 3 having the photosensitizing dye adsorbed thereon formed on the electroconductive support 8 and the support on a counter electrode side 9, materials that can transport an electron, a hole or an ion can be used. For example, a hole transporting material such as polyvinyl carbazole, an electron transporting material such as tetranitrofluorenone, an electroconductive polymer such as polypyrrol, a liquid electrolyte, and an ionic electroconductive material such as a polymer solid electrolyte, can be used.

Illustrative of the redox pairs for a liquid electrolyte are I⁻/I₃⁻, Br⁻/Br₃³¹ and quinone/hydroquinone pairs. In the case of I⁻/I₃⁻, for example, lithium iodide and iodine may be used. As a solvent for the electrolyte, there may be used an electrochemically inert solvent capable of dissolving the electrolyte in a large amount, such as acetonitrile or propylene carbonate.

The following examples will further illustrate the present invention.

### EXAMPLE 1

### Preparation of 4,4′-Diethoxycarbonyl-4″(hexadecyl)-4′″(nonadecyl)-2,2′:6′,2″:6″,2′″-quaterpyridine, a Compound of formula (II1)

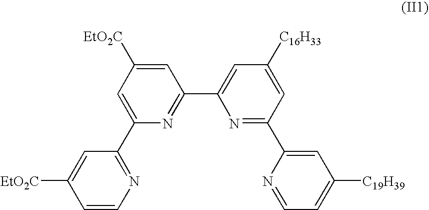 (a) Preparation of 2-Tributylstannyl-picolines.

To 2-bromo-picoline (28.4 g, 165 mmol) in absolute TH (250 mL) at −78° C. was added dropwise n-butyllithium (110 mL, 178 mmol, 1.6 M in hexane). After the solution was stirred at −78° C. for 90 min, tributyltinchloride (53.6 mL, 198 mmol) was added, and the mixture was allowed to warm to room temperature. Water (90 mL) was poured into the reaction mixture, and the phases were separated. The aqueous layer was extracted with diethyl ether (4×200 mL). The combined organic phases were dried over Na₂SO₄, and the solvent was removed in vacuo. The resulting oil was purified by fractionated Kugelrohr distillation, colorless liquid, bp 120° C. (2.5×10⁻⁵ mbar); Yield: 60%. Anal. C18H33NSn: calcd C, 56.56; H, 8.64; N, 3.67; found C, 56.22; H, 8.70; N, 3.21. MS (ESIMS): m/z: 383.2.

(b) Preparation of 2,6-Dihydroxy-4-methylpyridine:

A mixture of 2,6-Dihydroxy-3-cyano-4-methylpyridine (4.32 g, 28.8 mmol), concentrated H₂SO₄ (12 mL) and water (10 mL) was heated under reflux for 5 h. The mixture was cooled with ice and neutralized with solid NaHCO₃. The precipitate was filtered, washed with water and Et₂O and dried in vacuo to give a mixture of 2,6-Dihydroxy-4-methylpyridine and of the free acid, which was not decarboxylated. The mixture was used without further purification for the next reaction step. Yield: 72%. Anal. C6H7NO2: calcd C, 57.59; H, 5.64; N, 11.19; found C, 57.34; H, 5.55; N, 11.16;. MS (ESIMS): m/z: 125.0.

(c) Preparation of 2,6-Dibromo-4-methylpyridine:

2,6-Dihydroxy-4-methylpyridine (1.0 g, 7.93 mmol) and POBr₃ (7.26 g, 25.33 mmol) were ground and melted together at 140-150° C. for 1 h. After cooling, the mixture was quenched with water, neutralized with solid NaHCO₃ and extracted with CHCl₃ (3×100 mL). The combined organic phases were washed with water and purified by column chromatography on silica with hexane/EOAc (9/1, v/v) to give 2,6-Dibromo-4-methylpyridine as colorless oil. Yield: 58%. Anal. C6H5Br2N: calcd C, 28.72; H, 2.01; N, 5.58; found C, 28.58; H, 2.07; N, 5.46. MS (ESIMS): m/z: 250.8768

(d) Preparation of 6-Bromo-4,4′-dimethyl-2,2′-bipyridine:

2,6-Dibromo-4-methylpyridine (1 mmol), 2-Tributylstannyl-picolines (1 mmol) and (Ph₃P)4Pd (0.01 equiv) were heated under N₂ in toluene (50 mL) for 16 h. Upon cooling to room temperature aqueouus saturated NH₄Cl solution (20 mL) was added. The mixture was stirred for further 30 min and then filtered over Celite. The precipitate was washed with CH₂Cl₂ (50 mL) and the organic phase was separated. The aqueous phase was extracted with toluene. The combined organic phase were dried (MgSO₄) and the solvent was removed. Concentrated HCl (30 mL) was added to the residue and extracted with CH₂Cl₂. The aqueous phase was cautiously neutralized by solid NaOH. The product was then extracted with CH₂Cl₂ and drided. The solvent was removed and the product purified by chromatography on silica gel with CH₂Cl₂/hexane (1/2) as eluent. Yield: 25%. Anal. C12H11BrN2 calcd C, 54.77; H, 4.21; N, 10.65; found C, 54.54; H, 4.30; N, 10.45. MS (ESIMS): n/z: 262.0.

(e) Preparation of 6-Bromo-4,4′-Dicarboxy-2,2′bipyridine:

To a stirring solution of sulfuric acid (98%, 125 mL), 5.37 g (20.5 mmoles) of 6-Bromo-4,4′-dimethyl-2,2′-bipyridine was added. With efficient stirring, 24 g (81.5 mmoles) of potassium dichromate was then added in small portions, such that the temperature remained between 70 and 80° C. Occasional cooling in a water bath was usually necessary during the addition of potassium dichromate. After all the dichromate was added, the reaction stirred at room temperature until the temperature fell below 40° C. The deep green reaction mixture was poured into 800 mL of ice water and filtered. The solid was washed with water until the filtrate was colorless and allowed to dry. The resulting light yellow solid was then further purified by refluxing it in 170 mL of 50% nitric acid for 4 hours. This solution was poured over ice, diluted with 1 L of water and cooled to 5° C. The precipitate was filtered, washed with water (5×50 mL), then acetone (2×20 mL) and allowed to dry giving 6.2 g (Yield: 94%) of 6-Bromo-4,4′-Dicarboxy-2,2′bipyridine as a fine white solid. Anal. C12H7BrN2O4: calcd C, 44.61; H, 2.18; N, 8.67; found C, 44.23; H, 2.14; N, 8.56. MS (ESIMS): m/z: 322.0.

(f) Preparation of 6-Bromo-4,4′-Diethoxycarbonyl-2,2′bipyridine

To a suspension of 6-Bromo-4,4′-Dicarboxy-2,2′bipyridine (6.6 g, 20.5 mmol) in 400 mL of absolute ethanol was added 5 mL of concentrated sulfuric acid. The mixture was refluxed for 80 h to obtain a clear solution and then cooled to room temperature. Water (400 mL) was added and the excess ethanol removed under vacuum. The pH was adjusted to neutral with NaOH solution, and the resulting precipitate was filtered and washed with water (pH=7). The solid was dried to obtain 7.0 g (90%) of 6-Bromo-4,4′-Diethoxycarbonyl-2,2′bipyridine. Anal. C16H15BrN2O4: calcd C, 50.68; H, 3.99; N, 7.39; found C, 50.45; H, 3.92; N, 7.33. MS (ESIMS): m/z: 378.0.

(g) Preparation of 3-Oxo-nonadecanoic Acid Ethyl Ester

To a solution of sodium hydride (1.2 g, 50 mmol) in THF, distrilled ethylacetoacetate (4.16 g, 32 mmol) was added drop wise. The resulting mixture was stirred for 30 min at room temperature and then cooled at −78° C. A solution of n-butyllithium in hexane (16.1 mL, 35.2 mmol) was added dropwise. After stirring for an additional 1 h at 0° C., 1-bromohexadecane (19.1 mmol) in THF was added and the mixture was stirred for 12 h. Ethanol (15 mL) was added slowly at room temperature. The resulting solution was filtered through a Celite pad, concentrated in vacuo and purified by chromatography on silica gel to give the 3-Oxo- nonadecanoic acid ethyl ester as a solid. Yield: 78%. Anal. Calcd for C21H40O3: C, 74.07; H, 11.84; O, 14.09. Found: C, 73.98; H, 11.59; O, 14.25. MS (ESIMS): m/z: 340.3.

(h) Preparation of 3-cyano-2,6-dihydroxy-4-hexadecyl-pyridine

3-Oxo-nonadecanoic acid ethyl ester (3.8 g, 11.3 mmol), cyanoacetamide (0.95 g, 11.3 mmol) and piperidine (0.95 g, 11.3 mmol) in MeOH (3 mL) were heated under reflux for 24 h. The solvent was evaporated, and the residue was dissolved in hot water. The product was precipitated by addition of concentrated HCl, filtered, washed with ice water and CHCl₃ and dried in vacuo to give 3-cyano-2,6-dihydroxy-4-hexadecyl-pyridine as a white powder. Yield: 40%. Anal. Calcd for C22H36N2O2: C, 73.29; H, 10.06; N, 7.77; O, 8.88. Found: C, 73.35; H, 10.12; N, 7.85; O, 8.97. MS (ESIMS): m/z: 360.3.

(i) Preparation of 2,6-dihydroxy-4-hexadecyl-pyridine (9)

A mixture of 2,6-Dihydroxy-3-cyano-4-hexadecylpyridine (10.4 g, 28.8 mmol), concentrated H₂SO₄ (12 mL) and water (10 mL) was heated under reflux for 5 h. The mixture was cooled with ice and neutralized with solid NaHCO₃. The precipitate was filtered, washed with water and Et₂O and dried in vacuo to give a mixture of 2,6-dihydroxy-4-hexadecyl-pyridine and of the free acid, which was not decarboxylated. The mixture was used without further purification for the next reaction step. Yield: 72%. Anal. Calcd for C21H37NO2: C, 75.17; H, 11.12; N, 4.17; O, 9.54. Found: C, 75.03; H, 11.09; N, 4.25; O, 9.38. MS (ESIMS): m/z: 335.3.

(j) Preparation of 2,6-dibromo-4-hexadecyl-pyridine

2,6-dihydroxy-4-hexadecyl-pyridine (2.9 g, 7.93 mmol) and POBr₃ (7.26 g, 25.33 mmol) were ground and melted together at 140-150° C. for 1 h. After cooling, the mixture was quenched with water, neutralized with solid NaHCO₃ and extracted with CHCl₃ (3×100 mL). The combined organic phases were washed with water and purified by column chromatography on silica with hexane/EOAc (9/1, v/v) to give 2,6-dibromo-4-hexadecyl-pyridine as colorless oil. Yield: 53%. Anal. Calcd for C21H35Br2N: C, 54.67; H, 7.65; Br, 34.64; N, 3.04. Found: C, 54.84; H, 7.61; Br, 34.52; N, 3.11. MS (ESIMS): m/z: 461.1.

(k) Preparation of 4-Nonadecylpyridine

Into a 300-mL flask equipped with a mechanical stirrer, N₂ inlet, pressure-equalizing addition funnel, and thermostated oil bath, were added 14.8 g of sodium amide (0.38 mol) and 64.0 mL of 4-methylpyridine (61.1 g, 0.656 mol). The mixture was stirred under N₂ for 1 h while a color change to deep red was observed. A 110-mL sample of n-octadecyl chloride (95.0 g; 0.33 mol) was added to the rapidly stirred-reaction mixture over a period of 1.5 h. Shortly after addition was begun, the reaction was warmed to 60° C. to prevent solidification and was subsequently stirred overnight at 100° C. The reaction mixture was cooled to room temperature, diluted with 200 mL of chloroform, washed three times with 200 mL of H₂O, and reduced to dryness with the rotary evaporator. The resultant dark brown product was vacuum distilled three times at 0.07 mmHg to finally afford 48.8 g of constant-boiling (180° C. (0.07 mmHg)), white, waxy solid (0.141 mol, 43% yield based on n-octadecyl chloride). Anal. Calcd for C24H43N: C, 83.41; H, 12.54; N, 4.05. Found: C, 83.6; H, 12.7; N, 4.0. MS (ESIMS): m/z: 345.3.

(l) Preparation of 2-Amino-4-nonadecylpyridine

A mixture of 0.5 molar portion of 4-nonadecylpyridine, 0.59 mole of sodamide and 1.18 moles of N,N-dimethylaniline was heated at 150° C. for six hours. The reaction mixture, after cooling, was poured into water, and 2-Amino-4-nonadecylpyridine layer separated and dried over anhydrous potassium carbonate. After removal of solvent in vacuo the residue was stirred in petroleum ether and crystallized from ethyl acetate/ligroin. Yield: 45%.Anal. Calcd for C24H44N2: C, 79.93; H, 12.30; N, 7.77. Found: C, 79.63; H, 12.40; N, 7.60. MS (ESIMS): m/z: 360.3.

(m) 2-Bromo-4-nonadecylpyridine

Powdered 2-Amino-4-nonadecylpyridine (110.6 g, 0.31 mol) was added under vigorous stirring in portions to 48% hydrobromic acid (500 mL) at 20 to 30° C. in a 4-L glass reactor. After all of the compound was dissolved, the mixture was cooled at −20° C. To this suspension was added cooled bromine (44.3 mL, 0.86 mol) dropwise over 30 min, maintaining the temperature at −20° C. The resulting paste was stirred for 90 min at this temperature. Then sodium nitrite (56.6 g, 0.82 mol) in water (250 mL) was added dropwise. After that the reaction mixture was allowed to warm to 15° C. over 1 h and was stirred for an additional 45 min. The mixture was cooled to −20° C. and treated with cooled aqueous NaOH (222 g, 330 mL H₂O). During the addition the temperature was kept at −10° C. maximum. The mixture was allowed to warm to room temperature and stirred for 1 h. The mixture was extracted with ethyl acetate, the organic phase was dried with Na₂SO₄, and the solvent was removed in vacuo. The residue was subjected to distillation in vacuo to yield the desired. Yield: 50%. Anal. Calcd for C24H42BrN: C, 67.90; H, 9.97; N, 3.30. Found: C, 67.50; H, 9.87; N, 3.40. MS (ESIMS): m/z: 423.3.

(n) Preparation of 2-Tributyl(4-nonadecylpyridine-2-yl)stannane.

This compound was prepared by an analogous procedure to that described in Example 1 (step a). Yield: 55%. Anal. C36H69NSn: calcd C, 68.13; H, 10.96; N, 2.21; found C, 68.65; H,. 10.76; N, 2.27;. MS (ESIMS): m/z: 635.4.

(o) Preparation of 6-Bromo-4-hexadecyl-4′-nonadecyl-2,2′-bipyridine:

This compound was prepared by an analogous procedure to that described in Example 1 (step d). Yield: 25%. Anal. Calcd for C45H77BrN2: C, 74.45; H, 10.69; Br, 11.01;N, 3.86. Found: C, 74.59; H, 10.84; Br, 11.13; N, 3.82. MS (ESIMS): m/z: 724.5.

(p) Preparation of 6-tributylstannyl-4-hexadecyl-4′-nonadecyl-2,2′-bipyridine:

This compound was prepared by an analogous procedure to that described in Example 1 (step a). Yield: 55%. Anal. Calcd for C57H104N2Sn: C, 73.13; H, 11.20; N, 2.99. Found: C, 73.22; H, 11.28; N, 3.01. MS (ESIMS): m/z: 936.7.

(q) Preparation of 4,4′-Diethoxycarbonyl-4″(hexadecyl)-4′″(nonadecyl)-2,2′:6′,2″:6″,2′″-quaterpyridine:

This compound was prepared by an analogous procedure to that described in Example 1 (step d). Yield: 25% Anal. Calcd for C61H92N4O4: C, 77.50; H, 9.81; N, 5.93;. Found: C, 76.50; H, 9.81; N, 5.93;. MS (ESIMS): m/z: 944.71.

### EXAMPLE 2

### Preparation of 4,4′-Diethoxycarbonyl-4″(hexadecyl)- 4′″(didodecylmethyl)-2,2′:6′,2″:6″,2′″-quaterpyridine, a Compound of formula (II2)

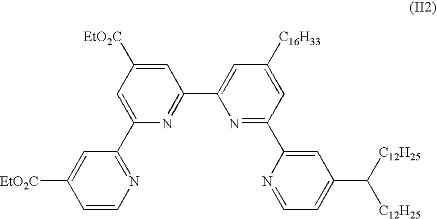 (a) Preparation of 4-( didodecylmethyl)pyridine:

A solution of butyllithium (1.6 M in hexane; 2.05 equiv.) was added to a solution of diisopropylamine (0.2 M; 2.1 equiv.) in dry ether at −15° C. After stirring for 30 min, freshly distilled 4-methylpyridine (1 eqiv.) was added dropwise. The resulting red solution was stirred for 15 min at −15° C. and then a solution of alkyl halide (1 M; 2.05 equiv.) in dry ether was added in one portion. The mixture was stirred overnight at room temperature. Ether was added and the reaction mixture washed twice with 1 M NH₄Cl solution, dried with Na₂SO₄ and evaporated to dryness. The product was purified by chromatography on Al₂O₃ (neutral), gradient elution with hexane and finally hexane/ether (5:1) gave the product in 70%. Anal. C30H55N: calcd C, 83.84; H, 12.90; N, 3.26; found C, 83.55; H, 12.84; N, 3.21. MS (ESIMS): m/z: 429.4.

(b) Preparation of 2-Amino-4-didodecylmethyl-pyridine:

This compound was prepared by an analogous procedure to that described in Example 1 (step 1). Yield: 46%. Anal. C30H56N2: calcd C, 81.01; H, 12.69; N, 6.30; found C, 81.01; H, 12.69; N, 6.30. MS (ESIMS): m/z: 444.78.

(c) Preparation of 2-Bromo-4-didodecylmethyl-pyridine:

This compound was prepared by an analogous procedure to that described in Example 1 (step m). Yield: 54%. Anal. C30H54BrN: calcd C, 70.84; H, 10.70; N, 2.75; found C, 70.45; H, 10.67; N, 2.69. MS (ESIMS): m/z: 507.3.

(d) Preparation of 2-Tributyl(4-didodecylmethyl-2-yl)stannane:

This compound was prepared by an analogous procedure to that described in Example 1 (step a). Yield: 58%. Anal. C42H81NSn: calcd C, 70.18; H, 11.36; N, 1.95; found C, 70.0; H, 11.31; N, 1.97. MS (ESIMS): m/z: 719.5.

(e) Preparation of 2,6-dibromo-4-hexadecyl-pyridine

This compound was prepared by an analogous procedure to that described in Example 1 (step g-j).

(f) Preparation of 6-Bromo-4- hexadecyl-4′-didodecylmethyl-2,2′-bipyridine

This compound was prepared by an analogous procedure to that described in Example 1 (step d). Yield: 25%. Anal. for C51H89BrN2; Calcd: C, 75.61; H, 11.07; N, 3.46. Found: C, 75.32; H, 11.00; N, 3.55 MS (ESIMS): m/z: 808.62.

(g) Preparation of 6-tributylstannyl-4-hexadecyl-4′- didodecylmethyl-2,2′-bipyridine:

This compound was prepared by an analogous procedure to that described in Example 1 (step a). Yield: 58%. Anal. Calcd for C63H116N2Sn: C, 74.16; H, 11.46; N, 2.75. Found: C, 74.55; H, 11.36; N, 2.69. MS (ESIMS): m/z: 1020.82.

(h) Preparation of 4,4′-Diethoxycarbonyl-2,2′bipyridine:

This compound was prepared by an analogous procedure to that described in Example 1 (step a-f).

(i) Preparation of 4,4′-Diethoxycarbonyl-4″(hexadecyl)-4′″-didodecylmethyl 2,2″:6′,2″:6″,2′″-quaterpyridine:

This compound was prepared by an analogous procedure to that described in Example 1 (step d). Yield: 25%. Anal. Calcd for C67H104N4O4: C, 78.16; H, 10.18; N, 5.44;. Found: C, 78.16; H, 10.18; N, 5.44;. MS (ESIMS): m/z: 1028.81.

### EXAMPLE 3

### Preparation of 4-Ethoxycarbonyl-4′,4″-bis(hexadecyl)-4′″-nonadecyl-2,2′:6′,2″:6″,2′″- quaterpyridine, a Compound of formula (II3)

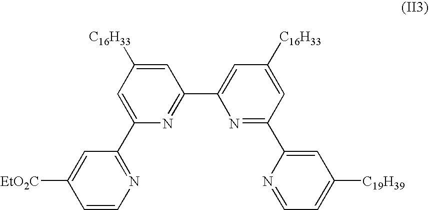 (a) Preparation of 6-tributylstannyl-4-hexadecyl-4′-nonadecyl-2,2′-bipyridine

This compound was prepared by an analogous procedure to that described in Example 1 (step g-p).

(b) Preparation of 2,6-dibromo-4-hexadecyl-pyridine

This compound was prepared by an analogous procedure to that described in Example 1 (step g-j).

(c) Preparation of 2-Bromo-4-carboxy-pyridine

This compound was prepared by an analogous procedure to that described in Example 1 (step e). Yield: 88%. Anal. Calcd for C6H4BrNO2: C, 35.67; H, 2.00; N, 6.93; Found: C, 35.75; H, 2.03; N, 6.90. MS (ESIMS): m/z: 200.9425.

(d) Preparation of 2-Bromo-4-etoxycarbonyl-pyridine

This compound was prepared by an analogous procedure to that described in Example 1 (step f). Yield: 90%. Anal. Calcd for C8H8BrNO2: C, 41.77; H, 3.50; N, 6.09;. Found: C, 41.87; H, 3.45; N, 6.03. MS (ESIMS): m/z: 229.0.

(e) Preparation of 2-tributylstannyl-4-ethoxycarbonyl-pyridine:

This compound was prepared by an analogous procedure to that described in Example 1 (step a). Yield: 90%. Anal. Calcd for C20H35NO2Sn: C, 54.57; H, 8.01; N, 3.18. Found: C, 54.34; H, 8.09; N, 3.22. MS (ESIMS): m/z: 441.17.

(f) Preparation of 6-Bromo-4-hexadecyl-4′-ethoxycarbonyl-2,2′-bipyridine:

This compound was prepared by an analogous procedure to that described in Example 1 (step d). Yield: 42%. Anal. Calcd for C29H43BrN2O2: C, 65.53; H, 8.15; N, 5.27;. Found: C, 65.53; H, 8.15; N, 5.27;. MS (ESIMS): m/z: 530.25.

(g) Preparation of 4-Ethoxycarbonyl-4′,4″-bis(hexadecyl)-4′″-nonadecyl-2,2′:6′,2″:6″,2′″-quaterpyridine

This compound was prepared by an analogous procedure to that described in Example 1 (step d). Yield: 46%. Anal. Calcd for C74H120N4O2: C, 80.96; H, 11.02; N, 5.10;. Found: C, 80.45; H, 11.22; N, 5.14;. MS (ESIMS): m/z: 1096.9.

### EXAMPLE 4

### Preparation of 4,4′,4″-Triethoxycarbonyl-4′″-nonadecyl-2,2′:6′,2″:6″,2′″-quaterpyridine, a Compound of formula (II4)

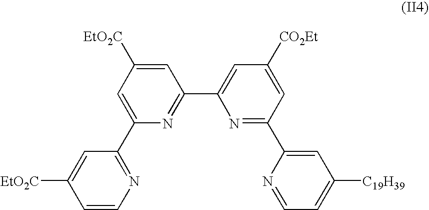 (a) Preparation of 6-Bromo-4,4′-Diethoxycarbonyl-2,2′bipyridine:

This compound was prepared by an analogo us procedure to that described in Example 1 (step a-f).

(b) Preparation of 2-Tributyl(4-nonadecylpyridine-2-yl)stannane.

This compound was prepared by an analogous procedure to that described in Example 1 (step k-n).

(c) Preparation of 2,6-Dibromo-4-carboxy-pyridine

This compound was prepared by an analogous procedure to that described in Example 1 (step j). Yield: 58%. Anal. Calcd for C6H3Br2NO2: C, 25.65; H, 1.08; Br, 56.89; N, 4.99; O, 11.39. Found: C, 25.52; H, 1.14; Br, 56.77; N, 5.04; O, 11.25. (ESIMS): m/z: 280.9.

(d) Preparation of 2,6-Dibromo-4-ethoxycarbonyl-pyridine

This compound was prepared by an analogous procedure to that described in Example 1 (step f). Yield: 88%. Anal. Calcd for C8H7Br2NO2: C, 31.10; H, 2.28; Br, 51.73;N, 4.53; O, 10.36. Found: C, 31.22.H, 2.15Br, 51.81N, 4.45 O, 10.31. (ESIMS): m/z: 308.9.

(e) Preparation of 6-Bromo-4-ethoxycarbonyl-4′-hexadecyl-2,2′-bipyridine:

This compound was prepared by an analogous procedure to that described in Example 1 (step d). Yield: 38%. Anal. Calcd for C32H49BrN2O2: C, 67.00; H, 8.61; N, 4.88. Found: C, 67.00; H, 8.61; N, 4.88. MS (ESIMS): m/z: 572.3.

(f) Preparation of 2-tributylstannyl-4-ethoxycarbonyl-4′-hexadecyl-2,2′-bipyridine:

This compound was prepared by an analogo us procedure to that described in Example 1 (step a). Yield: 58%. Anal. Calcd for C44H76N2O2Sn: C, 67.42; H, 9.77; N, 3.57;. Found: C, 67.04 H, 9.69; N, 3.51. MS (ESIMS): m/z: 784.5.

(g) Preparation of 4,4′,4″-Triethoxycarbonyl-4′″-nonadecyl-2,2′:6′,2″:6″,2′″-quaterpyridine

This compound was prepared by an analogous procedure to that described in Example 1 (step d). Yield: 35%. Anal. Calcd for C48H64N4O6: C, 72.70; H, 8.13; N, 7.06. Found: C, 72.56; H, 8.09; N, 7.11. MS (ESIMS): m/z: 792.5.

### EXAMPLE 5

### Preparation of 4,4′,4″-Triethoxycarbonyl-4′″-didodecylmethyl -2,2′:6′,2″:6″,2′″-quaterpyridine, a Compound of formula (II5)

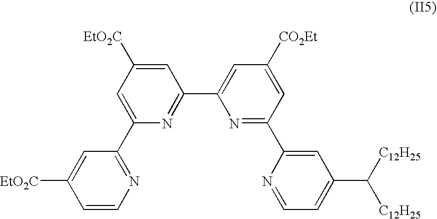 (a) Preparation of 4,4′-Diethoxycarbonyl-2,2′bipyridine:

This compound was prepared by an analogous procedure to that described in Example 1 (step a-f).

(b) Preparation of 2-Tributyl(4-didodecylmethyl-2-yl)stannane:

This compound was prepared by an analogous procedure to that described in Example 2 (step a-d)

(c) Preparation of 2,6-Dibromo-4-carboxy-pyridine This compound was prepared by an analogous procedure to that described in Example 4 (step c).

(d) Preparation of 2,6-Dibromo-4-ethoxycarbonyl-pyridine

This compound was prepared by an analogous procedure to that described in Example 4 (step d).

(e) Preparation of 6-Bromo-4- ethoxycarbonyl-4′-didodecylmethyl-2,2′-bipyridine:

This compound was prepared by an analogous procedure to that described in Example 1 (step d). Yield: 38%. Anal. Calcd for C38H61BrN2O2: C, 69.38; H, 9.35; N, 4.26. Found: C, 69.38; H, 9.35; N,. 4.26. MS (ESIMS): m/z: 657.8

(f) Preparation of 2-tributylstannyl-4-ethoxycarbonyl-4′-didodecylmethyl -2,2′-bipyridine:

This compound was prepared by an analogo us procedure to that described in Example 1 (step a). Yield: 44%. Anal. Calcd for C50H88N2O2Sn: C, 69.19; H, 10.22; N, 3.23. Found: C, 69.10; H, 10.27; N, 3.29. MS (ESIMS): m/z: 868.6.

(g) Preparation of 4,4′,4″-Triethoxycarbonyl-4′″-didodecylmethyl -2,2′:6′,2″:6″,2′″-quaterpyridine

This compound was prepared by an analogous procedure to that described in Example 1 (step d). Yield: 43%. Anal. Calcd for C54H76N4O6: C, 73.94; H, 8.73; N, 6.39; Found: C, 73.94; H, 8.73; N, 6.39;. MS (ESIMS): m/z: 877.2.

### EXAMPLE 6

### Preparation of 4,4′″-bis(nonadecyl)-4′4″-diethoxycarbonyl-2,2′:6′,2″:6″,2′″-quaterpyridine, a Compound of formula (II6)

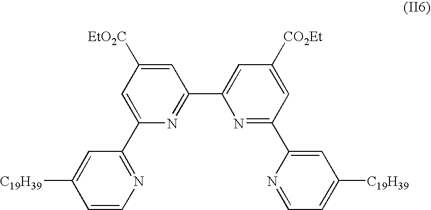 (a) Preparation of 6-Bromo-4-ethoxycarbonyl-4′-nonadecyl-2,2′-bipyridine:

This compound was prepared by an analogous procedure to that described in Example 4 (step e). Yield: 39%. Anal. Calcd for C32H49BrN2O2: C, 67.00; H, 8.61; N, 4.88;. Found: C, 67.12; H, 8.57; N, 4.82;. MS (ESIMS): m/z: 572.3.

(b) Preparation of 2-tributylstannyl-4-ethoxycarbonyl-4′- nonadecyl-2,2′-bipyridine:

This compound was prepared by an analogo us procedure to that described in Example 4 (step f). Yield: 58%. Anal. Calcd for C44H76N2O2Sn: C, 67.42; H, 9.77; N, 3.57. Found: C, 67.55; H, 9.69; N, 3.53. MS (ESIMS): m/z: 784.5.

(c) 4,4′″-bis(nonadecyl)-4′4″-diethoxycarbonyl-2,2′:6′,2″:6″,2′″-quaterpyridine,

This compound was prepared by an analogous procedure to that described in Example 1 (step d). Yield: 42%. Anal. Calcd for C64H98N4O4: C, 77.84; H, 10.00; N, 5.67. Found: C, 77.77; H, 10.06; N, 5.59. MS (ESIMS): m/z: 986.8.

### EXAMPLE 7

### Preparation of 4,4′-Bis(diethylmethylphosphonate)-4″(hexadecyl)-4′″(nonadecyl)-2,2′:6′,2″:6″,2′″-quaterpyridine, a Compound of formula (II7)

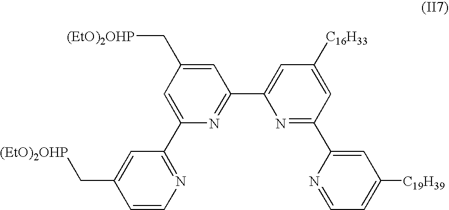 (a) Preparation of 4,4′-Diethoxycarbonyl-4″(hexadecyl)-4′″(nonadecyl)-2,2′:6′,2″:6″,2′″-quaterpyridine:

This compound was prepared by an analogous procedure to that described in Example 1.

(b) Preparation of 4,4′-Bis(hydroxymethyl)-4″(hexadecyl)-4′″(nonadecyl)-2,2′:6′,2″:6″,2′″-quaterpyridine:

An 8.2 g amount of sodium borohydride was added to a suspension of 4,4′-Diethoxycarbonyl-4″(hexadecyl)-4′″(nonadecyl)-2,2′:6′,2″:6″,2′″-quaterpyridine (6.4 g, 10.0 mmol) in 200 mL of absolute ethanol. The mixture was refluxed for 3 h and cooled to room temperature, and then 200 mL of an ammonium chloride saturated water solution was added to decompose the excess borohydride. The ethanol was removed under vacuum and the precipitated solid dissolved in a minimal amount of water. The resulting solution was extracted with ethyl acetate (5×200 mL) and dried over sodium sulfate, and the solvent was removed under vacuum. The desired solid was obtained in 80% yield and was used without further purification. Anal. C57H88N4O2: calcd C, 79.48; H,. 10.30; N, 6.50; found C, 79.56; H, 10.37; N, 6.57. MS (ESIMS): m/z: 860.7.

(c) Preparation of 4,4′-Bis(bromomethyl)-4″(hexadecyl)-4′″(nonadecyl)-2,2′:6′,2″:6″,2′″-quaterpyridine

4,4′-Bis(hydroxymethyl)-4″(hexadecyl)-4′″(nonadecyl)-2,2′:6′,2″-quaterpyridine (3.62 g, 4.2 mmol) was dissolved in a mixture of 48% HBr (20 mL) and concentrated sulfuric acid (6.7 mL). The resulting solution was refluxed for 6 h and then allowed to cool to room temperature, and 40 mL of water was added. The pH was adjusted to neutral with NaOH solution and the resulting precipitate filtered, washed with water (pH) 7), and air-dried. The product was dissolved in chloroform (40 mL) and filtered. The solution was dried over magnesium sulfate and evaporated to dryness, yielding 3.5 g of 4,4′-Bis(bromomethyl)-4″(hexadecyl)-4′″(nonadecyl)-2,2′:6′,2″:6″,2′″-quaterpyridine (85% yield) as a white powder. Anal. C57H86Br2N4: calcd C, 69.35; H, 8.78; N, 5.68; found C, 69.44; H, 8.69; N, 5.74. MS (ESIMS): m/z: 984.5.

(d) Preparation of 4,4′-Bis(diethylmethylphosphonate)-4″(hexadecyl)-4′″(nonadecyl)-2,2′:6′,2″:6″,2′″-quaterpyridine

A chloroform (20 mL) solution of 4,4′-Bis(bromomethyl)-4″(hexadecyl)-4′″(nonadecyl)-2,2′:6′,2″:6″,2′″-quaterpyridine (4.33 g, 4.4 mmol) and 15 mL of triethyl phosphite was refluxed for 3 h under nitrogen. The excess phosphite was removed under high vacuum, and then the crude product was purified by column chromatography on silica gel (eluent ethyl acetate/ methanol 80/20) yielding 3.87 g (80%) of 4,4′-Bis(diethylmethylphosphonate)-4″(hexadecyl)-4′″(nonadecyl)-2,2′:6′,2″-quaterpyridine. Anal. C65H106N4O6P2: calcd C, 70.88; H, 9.70; N, 5.09; Found C, 70.67; H, 9.74; N, 5.00;. MS (ESIMS): m/z: 1100.8.

### EXAMPLE 8 (Complex 1a)

### Preparation of the Complex of Formula RuL(NCS)₂(TBA), Wherein L is 4,4′-Dicarboxy-4″(hexadecyl)-4′″(nonadecyl)-2,2′:6′,2″:6″,2′″-quaterpyridine (Formula II1), and TBA is Tetrabutylammonium Ion.

(a) Preparation of Ru(4,4′- Diethoxycarbonyl -4″(hexadecyl)-4′″(nonadecyl)-2,2′:6′,2″:6″,2′″-quaterpyridine)Cl₂

Ru(p-cymene)Cl₂ (61 mg, 0.1 mmol) was dissolved in ethanol (50 mL) by heating. To this orange solution was added 4,4′-Diethoxycarbonyl-4″(hexadecyl)-4′″(nonadecyl)-2,2′:6′,2″:6″,2′″-quaterpyridine (100 mg, 0.11 mmol), and the mixture was refluxed for 6 h. The black precipitate that formed was filtered and washed with ethanol to yield the title compound as a dark powder. Yield 90%. Anal. Calcd for C₆₁H₉₂Cl₂N₄O₄Ru: C, 65.57; H, 8.30; N, 5.01. Found: C, 65.78; H, 8.42; N, 4.93. MS (ESIMS): m/z: 1116.6.

(b) Preparation of Ru(4,4′-dicarboxy-4″(hexadecyl)-4′″(nonadecyl)-2,2′:6′,2″:6″,2′″-quaterpyridine)(NCS)₂

To a solution of complex Ru(4,4′- Diethoxycarbonyl -4″(hexadecyl)-4′″(nonadecyl)-2,2′:6′,2″:6″,2′″-quaterpyridine)Cl₂ (100 mg, 0.09 mmol) in DMF (50 mL) was added ammonium thiocyanate (350 mg, 4.6 mmol) in 10 ml water. The reaction mixture was heated at 140° C. for 3 h. Then, 10 mL of Et₃N was added, and the solution was refluxed for further 24 h to hydrolyze the ester groups on the quaterpyridine ligand. The solution was allowed to cool to room temperature. The black precipitate that formed was filtered, washed thoroughly with water and dried under vacuum to yield the title compound as a dark powder. The resulting crude complex was further purified using a sephadex LH 20. Yield 90%) Anal. Calcd for C₅₉H₈4N6O4RuS₂: C, 64.04; H, 7.65; N, 7.59. Found: C, 64.54; H, 7.54; N, 7.72. MS (ESIMS): m/z: 1106.5.

(c) Preparation of Ru(4,4′-dicarboxy-4″(hexadecyl)-4′″(nonadecyl)-2;2′:6′,2″:6″,2′″-quaterpyridine)(NCS)₂(TBA)

Powder Ru(4,4′-dicarboxy-4″(hexadecyl)-4′″(nonadecyl)-2,2 ′:6′,2″:6″,2′″-quaterpyridine)(NCS)₂ (80 mg) was dissolved in 15 ml of 0.1 M aqueous tetrabutylammonium hydroxide (TBAOH) and the mixture heated to 110° C., for 4 h. (the pH of the solution was ca. 11). The resulting solution was filtered to remove a small amount of insoluble material and the pH adjusted to 5.0 with 0.1 M hydrochloric acid. A dense precipitate formed immediately but the suspension was nevertheless refrigerated overnight prior to filtration to collect the product. After allowing to cool to (25° C.) room temperature, it was filtered through a sintered glass crucible and dried under vacuum. Yield: 68%. Anal. Calcd for C₇₅H₁₁₉N₇O₄RuS₂: C, 66.83; H, 8.90; N, 7.27. Found: C, 66.73; H, 8.96; N, 7.43. MS (ESIMS): m/z: 1347.8.

### EXAMPLE 9 (Complex 1b)

### Preparation of the Complex of Formula RuL(CN)₂(TBA), Wherein L is 4,4′-Dicarboxy-4″(hexadecyl)-4′″(nonadecyl)-2,2′:6′,2″:6″,2′″-quaterpyridine, (formula II1)

(a) Preparation of Ru(4,4′-diethoxycarbonyl-4″(hexadecyl)-4′″(nonadecyl)-2,2′:6′,2″:6″,2′″- quaterpyridine)Cl₂

This compound was prepared by an analogous procedure to that described in Example 8 (step a).

(b) Preparation of Ru(4,4′-dicarboxy-4″(hexadecyl)-4′″(nonadecyl)-2,2′:6′,2″:6″,2′″-quaterpyridine)(CN)₂

To a solution of complex Ru(4,4′-diethoxycarbonyl-4″(hexadecyl)-4′″(nonadecyl)-2,2′:6′,2″:6″,2′″- quaterpyridine)Cl₂ (100 mg, 0.09 mmol) in DMF (50 mL) was added potassium cyanate (300 mg, 4.6 mmol) in 10 ML water. The reaction mixture was heated at 140° C. for 3 h. The solution was allowed to cool to room temperature. Then, 10 mL of Et₃N was added, and the solution was refluxed for further 24 h to hydrolyze the ester groups on the quaterpyridine ligand. The black ppt which formed was filtered, washed thoroughly with water and dried under vacuum to yield the title compound as a dark powder. The resulting crude complex was further purified using a sephadex LH 20. Yield 90%. Anal. Calcd for C₅₉H₈₄N₆O₄Ru: C, 67.98; H, 8.12; N, 8.06. Found: C, 67.75; H, 8.20; N, 8.14. MS (ESIMS): m/z: 1042.6.

(c) Preparation of Ru(4,4′-dicarboxy-4″(hexadecyl)-4′″(nonadecyl)-2,2′:6′,2″:6″,2′″-quaterpyridine)(CN)₂(TBA)

This compound was prepared by an analogous procedure to that described in Example 8 (step c). Yield: 65%. Anal. Calcd for C₇₅H₁₁₉N₇O₄Ru: C, 70.16; H, 9.34; N, 7.64. Found: C, 70.03; H, 9.23; N, 7.61. MS (ESIMS): m/z: 1283.8.

### EXAMPLE 10 (Complex 1c)

### Preparation of the Complex of Formula RuLI₂(TBA), Wherein L is 4,4′-Dicarboxy-4″(hexadecyl)-4′″(nonadecyl)-2,2′:6′,2″:6″,2′″-quaterpyridine, (Formula II1)

(a) Preparation of Ru(4,4′-diethoxycarbonyl-4″(hexadecyl)-4′″(nonadecyl)-2,2′:6′,2″:6″,2′″- quaterpyridine)Cl₂

This compound was prepared by an analogous procedure to that described in Example 8 (step a).

(b) Preparation of Ru(4,4′-dicarboxy-4″(hexadecyl)-4′″(nonadecyl)-2,2′:6′,2″:6″,2′″-quaterpyridine)I₂

To a solution of complex Ru(4,4′-dicarboxy-4″(hexadecyl)-4′″(nonadecyl)-2,2′:6′,2″:6″,2′″-quaterpyridine)Cl₂ in DMF was added potassium iodide in water. The reaction mixture was heated at 140° C. for 3 h. Then, 10 mL of Et₃N was added, and the solution was refluxed for further 24 h to hydrolyze the ester groups on the quaterpyridine ligand. The solution was allowed to cool to room temperature. The black ppt which formed was filtered, washed thoroughly with water and dried under vacuum to yield the title compound as a dark powder. The resulting crude complex was further purified using a sephadex LH 20. Yield 90%. Anal. Calcd for C₅₇H₈₄I₂N₄O₄Ru: C, 55.02; H, 6.81; N, 4.50. Found: C, 55.11; H, 6.78; N, 4.54. MS (ESIMS): m/z: 1244.4.

(c) Preparation of Ru(4,4′-dicarboxy-4″(hexadecyl)-4′″(nonadecyl)-2,2′:6′,2″:6″,2′″-quaterpyridine)I₂(TBA)

This compound was prepared by an analogous procedure to that described in Example 8 (step c). Yield: 60%. Anal. Calcd for C₇₃H₁₁₉I₂N₅O₄Ru: C, 59.02; H, 8.07; N, 4.71. Found: C, 59.09; H, 8.12; N, 4.67. MS (ESIMS): m/z: 1485.6.

### EXAMPLE 11 (Complex 2a)

### Preparation of the Complex of Formula RuL(NCS)₂(TBA), Wherein L is 4,4′-Dicarboxy-4″(hexadecyl)-4′″(didodecylmethyl)-2,2′:6′,2″:6″,2′″-quaterpyridine, (Formula II2)

This compound was prepared by an analogous procedure to that described in Example 8. Yield: 61%. Anal. Calcd for C8₁H₁₃₁N₇O₄RuS₂: C, 67.93; H, 9.22; N, 6.85; Found: C, 67.65; H, 9.27; N, 6.79;. MS (ESIMS): m/z: 1431.9.

### EXAMPLE 12 (Complex 2b)

### Preparation of the Complex of Formula RuL(CN)₂(TBA), Wherein L is 4,4′-Dicarboxy-4″(hexadecyl)-4′″(didodecylmethyl)-2,2′:6′,2″:6″,2′″-quaterpyridine, (Formula II2)

This compound was prepared by an analogous procedure to that described in Example 9. Yield: 60%. Anal. Calcd for C₈₁H₁₃₁N₇O₄Ru: C, 71.11; H, 9.65; N, 7.17;. Found: C, 71.01; H, 9.72; N, 7.25;. MS (ESIMS): m/z: 1367.9.

### EXAMPLE 13 (Complex 2c)

### Preparation of the Complex of Formula RuLI₂(TBA), Wherein L is 4,4′-Dicarboxy-4″(hexadecyl)-4′″(didodecylmethyl)-2,2′:6′,2″:6″,2′″-quaterpyridine, (Formula II2)

This compound was prepared by an analogous procedure to that described in Example 10. Yield: 60%. Anal. Calcd for C₇₉H₁₃₁I₂N₅O₄Ru: C, 60.44; H, 8.41; N, 4.46;. Found: C, 60.52; H, 8.37; N, 4.51; MS (ESIMS): m/z:1569.7.

### EXAMPLE 14 (Complex 3a)

### Preparation of the Complex of Formula RuL(NCS)₂, Wherein L is 4-Carboxy-4′,4″-bis(hexadecyl)-4′″-nonadecyl-2,2′:6′,2″:6″,2′″-quaterpyridine, (Formula II3)

This compound was prepared by an analogous procedure to that described in Example 8. Yield: 58% Anal. Calcd for C74H116N6O2RuS2: C, 69.06; H, 9.09; N, 6.53;. Found: C, 69.00; H, 9.13; N, 6.55;. MS (ESIMS): m/z: 1286.8.

### EXAMPLE 15 (Complex 3b)

### Preparation of the Complex of Formula RuL(CN)₂, Wherein L is 4-Carboxy-4′,4″-bis(hexadecyl)-4′″-nonadecyl-2,2′:6′,2″:6″,2′″-quaterpyridine, (Formula II3)

This compound was prepared by an analogous procedure to that described in Example 9. Yield: 55% Anal. Calcd for C₇₄H₁₁₆N₆O₂Ru: C, 72.68; H, 9.56; N, 6.87;. Found: C, 72.49; H, 9.52; N, 6.92;. MS (ESIMS): m/z: 1222.8.

### EXAMPLE 16 (Complex 4a)

### Preparation of the Complex of Formula RuL(NCS)₂(TBA)₂, Wherein L is 4,4′,4″-Tricarboxy-4′″-nonadecyl-2,2′:6′,2″:6″,2′″-quaterpyridine, (Formula II4)

This compound was prepared by an analogous procedure to that described in Example 8. Yield: 56% Anal. Calcd for C₇₆H₁₂₂N₈O₆RuS₂: C, 64.78; H, 8.73; N, 7.95;. Found: C, 64.67; H, 8.79; N, 7.87. MS (ESIMS): m/z: 1408.8.

### EXAMPLE 17 (Complex 4b)

### Preparation of the Complex of Formula RuL(CN)₂(TBA)₂, Wherein L is 4,4′,4″-Tricarboxy-4′″-nonadecyl-2,2′:6′,2″:6″,2′″-quaterpyridine, (Formula II4)

This compound was prepared by an analogous procedure to that described in Example 9. Yield: 62%. Anal. Calcd for C₇₆H₁₂₂N₈O₆Ru: C, 67.87; H, 9.14; N, 8.33;. Found: C, 67.55; H, 9.12; N, 8.37;. MS (ESIMS): m/z: 1344.85.

### EXAMPLE 18 (Complex 5a)

### Preparation of the Complex of Formula RuL(NCS)₂(TBA)₂, Wherein L is 4,4′,4″-Tricarboxy-4′″-didodecylmethyl-2,2′:6′,2″:6″,2′″-quaterpyridine, (Formula II5)

This compound was prepared by an analogous procedure to that described in Example 8. Yield: 53% Anal. Calcd for C₈₂H₁₃₄N8O₆RuS₂: C, 65.96; H, 9.05; N, 7.50;: Found: C, 65.79; H, 9.11; N, 7.66;. MS (ESIMS): m/z: 1492.89.

### EXAMPLE 19 (Complex 5b)

### Preparation of the Complex of Formula RuL(CN)₂(TBA)₂, Wherein L is 4,4′,4″-Tricarboxy-4′″-didodecylmethyl-2,2′:6′,2″:6″,2′″-quaterpyridine, (Formula II5)

This compound was prepared by an analogous procedure to that described in Example 9. Yield: 54%. Anal. Calcd for C₈₂H₁₃₄N₈O₆Ru: C, 68.92; H, 9.45; N, 7.84; Found: C, 68.78; H, 9.49; N, 7.89;. MS (ESIMS): m/z: 1428.95.

### EXAMPLE 20 (Complex 6a)

### Preparation of the Complex of Formula RuL(NCS)₂(TBA), Wherein L is 4,4′″-bis(nonadecyl)-4,4″-dicarboxy-2,2′:6′,2″:6″,2′″-quaterpyridine, (Formula II6)

This compound was prepared by an analogous procedure to that described in Example 8. Yield: 58%. Anal. Calcd for C₇₈H₁₂₅N₇O₄RuS₂: C, 67.39; H, 9.06; N, 7.05. Found: C, 67.70; H, 9.11; N, 7.00. MS (ESIMS): m/z: 1389.8.

### EXAMPLE 21

### Preparation of Sensitized Semiconductor Electrode

Nanocrystalline TiO₂ films of about 20 μm were prepared by spreading a viscous dispersion of colloidal TiO₂ particles (Sloaronix) on a conducting glass support (Asahi TCO glass, fluorine-doped SnO₂ overlayer, transmission>85% in the visible, sheet resistance 7-8 ohms/square) with heating under air for 30 min at 500° C. The performance of the film as a sensitized photoanode was improved by further deposition of TiO₂ from aqueous TiCl₄ solution. A freshly prepared aqueous 0.2 M TiCl₄ solution applied onto the electrode. After being left for 20 min at 70° C. in a closed chamber, the electrode was washed with distilled water. Immediately before being dipped into the dye solution, it was fired again for 30 min at 500° C. in air. After cooling under a continuous argon flow the glass sheet is immediately transferred to a 2×10⁻⁴ M solution in 1:1 acetonitrile: n-butanol of the tetrabutylammonium salt of ruthenium complex of 1a (example 8), this solution further containing 40 mM of deoxycholic acid as a co-adsorbent. The adsorption of photosensitizer from the dye solution is allowed to continue for 15 hours after that the glass sheet is withdrawn and washed briefly with absolute ethanol. The TiO₂ layer on the sheet assumed a black color owing to the photosensitive coating.

### Preparation of Solar Cell

A solar cell (size: 0.25 cm²) was fabricated using the above electrode and a counter electrode, which was a platinum electrode, obtained by vacuum-deposition of platinum on a conductive glass. The platinum layer had a thickness of 20 nm. An electrolyte solution to be placed between the two electrodes was a redox pair of I⁻/I₃⁻ obtained using 0.5 M 4-tert-butylpyridine, 0.1 M LiI, 0.6M 1,2-dimethyl-3-propyl imidazolium iodide and 0.1 M I₂ as solutes and a liquid of acetonitrile.

### Operation of Solar Cell

A potentiostat was used for measuring short-circuit electric current, open circuit voltage and fill factor. Experiments are carried out with a high pressure Xenon lamp equipped with appropriate filters to simulate AM 1.5 solar radiation. The intensity of the light is 100 mW/cm². The fill factor defined as the maximum electric power output of the cell divided by the product of open circuit voltage and short circuit current.

It was found that the thus constructed solar cell using sensitizer 1a gave a short-circuit electric current of 19 mA/cm², an open circuit voltage of 0.70 V and a fill factor FF of 0.70 under irradiation of AM 1.5 using solar simulator light (100 mW/cm²).

### COMPARISON EXAMPLE 1

Except that a dye represented by the following expression X was used, a dye sensitized solar cell was prepared similarly as has been described in example 21.

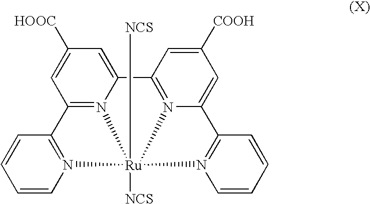

The expression's dye is described in T. Renouard, R.-A. Fallahpour, Md. Nazeeruddin, R. Humphry, S. I. Gorelsky, A. B. P. Lever, and M. Gratzel, Inorg. Chem. 41 (2002) 367, and is produced by the synthesis process described in the document.

The obtained solar cell gave a short circuit electric current of 18.7 mA/cm², an open circuit voltage of 0.64 V, a fill factor FF of 0.68, and a photoconversion efficiency (η) of 8.1% under irradiation of AM 1.5 using solar simulator light (1 kW/cm²).

### EXAMPLE 22

Except that sensitizer 4a in the above table was used, a dye sensitized solar cell was prepared similarly as has been described in example 21.

The obtained solar cell gave a short circuit electric current of 20.0 mA/cm², an open circuit voltage of 0.73 V, a fill factor FF of 0.68, and a photoconversion efficiency (η) of 9.9% under irradiation of AM 1.5 using solar simulator light (1 kW/cm²).

### EXAMPLE 23

Except that sensitizer 9c in the above table was used, a dye sensitized solar cell was prepared similarly as has been described in example 14.

The obtained solar cell gave a short circuit electric current of 19.9 mA/cm², an open circuit voltage of 0.72 V, a fill factor FF of 0.70, and a photoconversion efficiency (η) of 10.0% under irradiation of AM 1.5 using solar simulator light (1 kW/cm²).

Although the present invention has been described and illustrated in detail, it is clearly understood that the same is by way of illustration and example only and is not to be taken by way of limitation, the spirit and scope of the present invention being limited only by the terms of the appended claims.

1. A photosensitizing transition metal complex having the general formula (I)
MLX₂ (I)
in which M is a transition metal selected from a group consisting of Ru(II), Os(II), Fe(II), Re(I) and Tc(I);
L is a polypyridine ligand having the general formula (II); 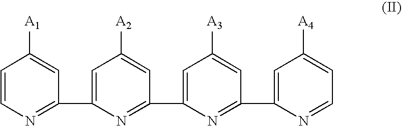
wherein A₁, A₂, A₃ and A₄ contain at least one anchoring group selected from a group consisting of —COOH, —COON(C₄H₉)₄, —PO(OH)₂, —PO(OR₁)₂ (where R₁ is an alkyl group having 1-30 carbon atoms), and —CO(NHOH), and at least one group selected from a group consisting of an alkyl group having 1 to 50 carbon atoms, an alkylamide group having 2 to 50 carbon atoms and an aralkyl group having 7 to 50 carbon atoms, and in the case where there remains any one of A₁, A₂, A₃ and A₄, it may be a hydrogen atom; and
X is a ligand selected from a group consisting of NCS⁻, Cl⁻, Br⁻, I⁻, CN⁻, NCO⁻, H₂O and pyridine group which may be substituted by vinyl, primary, secondary or tertiary amine, alkylthio, arylthio, hydroxyl or C₁₋₃₀ alkyl.

2. A photosensitizing transition metal complex of claim 1, which is a complex the formula (I) in which M is Ru(II) or Os(II);
X is NCS⁻ or CN⁻,
L is a polypyridine ligand having the subformula (IIa): 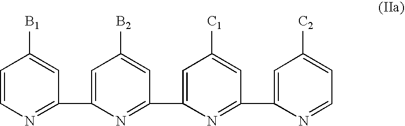
where B₁ and B₂ are —COOH, —COON(C₄H₉)₄ or —PO(OH)₂; C₁ and C₂ are, the same or different, a hydrogen atom, an alkyl group having 6-30 carbon atoms, provided that any one of C₁ and C₂ is different from a hydrogen atom.
B₁, B₂, C₁ and C₂ of the subformula (IIa) are as follows:

| B₁ | B₂ | C₁ | C₂ |
|---|---|---|---|
| COOH | COOH | H | nC₁₁H₂₃ |
| COOH | COOH | H | nC₁₉H₃₉ |
| COOH | COOH | H | nCH(C₈H₁₇)₂ |
| COOH | COOH | H | nCH(C₁₂H₂₅)₂ |
| COOH | COOH | nC₁₀H₂₁ | nC₁₁H₂₃ |
| COOH | COOH | nC₁₆H₃₃ | nC₁₉H₃₉ |
| COOH | COOH | nC₁₀H₂₁ | nCH(C₈H₁₇)₂ |
| COOH | COOH | nC₁₆H₃₃ | nCH(C₁₂H₂₅)₂ |
| PO(OH)₂ | PO(OH)₂ | H | nC₁₉H₃₉ |
| PO(OH)₂ | PO(OH)₂ | nC₁₀H₂₁ | nC₁₁H₂₃ |
| PO(OH)₂ | PO(OH)₂ | nC₁₆H₃₃ | nC₁₉H₃₉ |

3. A photosensitizing transition metal complex of claim 1, which is a complex the formula (I) in which M is Ru(II) or Os(II);
X is NCS⁻ or CN⁻,
L is a polypyridine ligand having the subformula (IIb): 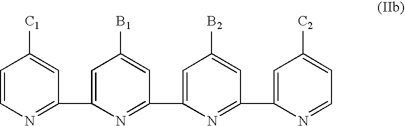
where B₁ and B₂ are —COOH, —COON(C₄H₉)₄ or —PO(OH)₂; C₁ and C₂ are, the same or different, a hydrogen atom, an alkyl group having 6-30 carbon atoms, provided that any one of C₁ and C₂ is different from a hydrogen atom.
B₁, B₂, C₁ and C₂ of the subformula (IIb) are as follows:

| C₁ | B₁ | B₂ | C₂ |
|---|---|---|---|
| H | COOH | COOH | nC₁₁H₂₃ |
| H | COOH | COOH | nC₁₉H₃₉ |
| H | COOH | COOH | nCH(C₁₂H₂₅)₂ |
| nC₁₁H₂₃ | COOH | COOH | nC₁₁H₂₃ |
| nC₁₉H₃₉ | COOH | COOH | nC₁₉H₃₉ |
| H | PO(OH)₂ | PO(OH)₂ | nC₁₉H₃₉ |
| nC₁₉H₃₉ | PO(OH)₂ | PO(OH)₂ | nC₁₉H₃₉ |

4. A photovoltaic cell comprising a support, a conductive layer formed on the support, and a porous semiconductor layer formed on the conductive layer, a counter electrode, and an electrolyte deposited there between, wherein the porous semiconductor layer carries a photosensitizing transition metal complex as claimed in claim 1.
